(19) United States
(12) Patent Application Publication
(10) Pub. No.: US 2019/0099820 A1
(43) Pub. Date: Apr. 4, 2019

(54) APPARATUS, SYSTEM, AND METHOD FOR MITIGATING WARPAGE OF CIRCUIT BOARDS DURING REFLOW PROCESSES

(71) Applicant: Juniper Networks, Inc., Sunnyvale, CA (US)

(72) Inventors: Peng Su, Santa Clara, CA (US); Gautam Ganguly, San Jose, CA (US); Marc D. Hartranft, Scotts Valley, CA (US)

(21) Appl. No.: 15/723,105

(22) Filed: Oct. 2, 2017

(51) Int. Cl. B23K 3/08; H05K 3/34

(52) U.S. Cl. CPC B23K 3/087; H05K 2203/0169; H05K 3/341

(57) ABSTRACT

The disclosed apparatus may include (1) a removable stiffening brace that (A) temporarily interfaces with a bottom surface of a circuit board during a reflow process in which at least one component is soldered to the circuit board and (B) provides structural support to the circuit board to prevent the circuit board from warping during the reflow process and (2) at least one fastener that secures the removable stiffening brace to the bottom surface of the circuit board during the reflow process. Various other apparatuses, systems, and methods are also disclosed.

### BACKGROUND

Electronic components (such as integrated circuits) are often soldered to circuit boards by way of a process known as reflow soldering. For example, prior to a reflow process, solder paste may be disposed on contact pads located on a circuit board, and then electronic components may be placed on top of the solder paste, which holds the electronic components in position atop their corresponding contact pads. After the electronic components have been put in place, the circuit board may undergo a reflow process that heats the solder paste to a certain temperature. The temperature must be hot enough to melt the solder paste such that, once cooled off, the solder forms permanent connection joints between the electronic components and their corresponding contact pads.

Unfortunately, circuit boards may pose and/or represent a significant challenge during the soldering process. For example, a reflow process may apply so much heat that the circuit board warps. This warpage may bend the circuit board such that permanent connection joints are unable to form between the connection terminals on certain electronic components and the corresponding contact pads on the circuit board. As a result, those electronic components may fail to achieve full connectivity with the remaining components laid out on the circuit board. Without full connectivity, the circuit board may fail to work as intended, leaving the computing device in which the circuit board is installed inoperable for its intended purpose.

The instant disclosure, therefore, identifies and addresses a need for apparatuses, systems, and methods for mitigating warpage of circuit boards during reflow processes.

### SUMMARY

As will be described in greater detail below, the instant disclosure generally relates to apparatuses, systems, and methods for mitigating warpage of circuit boards during reflow processes. In one example, an apparatus for accomplishing such a task may include (1) a removable stiffening brace that (A) temporarily interfaces with a bottom surface of a circuit board during a reflow process in which at least one component is soldered to the circuit board and (B) provides structural support to the circuit board to prevent the circuit board from warping during the reflow process and (2) at least one fastener that secures the removable stiffening brace to the bottom surface of the circuit board during the reflow process.

Similarly, a warpage-mitigation system incorporating the above-described apparatus may include (1) a removable stiffening brace that (A) temporarily interfaces with a bottom surface of the circuit board during a reflow process in which at least one component is soldered to the circuit board and (B) provides structural support to the circuit board to prevent the circuit board from warping during the reflow process and (C) includes at least one pin that is inserted through a hole formed in a circuit board and (2) at least one fastener that secures the removable stiffening brace to the bottom surface of the circuit board during the reflow process by locking the pin inserted through the hole to a top surface of the circuit board.

A corresponding method may include (1) temporarily interfacing a removable stiffening brace with a bottom surface of a circuit board during a reflow process in which at least one component is soldered to the circuit board, (2) securing the removable stiffening brace to the bottom surface of the circuit board by way of at least one fastener, and (3) providing, by way of the removable stiffening brace, structural support to the circuit board to prevent the circuit board from warping during the reflow process.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a block diagram of an exemplary apparatus for mitigating warpage of circuit boards during reflow processes.

FIG. 2 is a block diagram of an exemplary implementation of an apparatus for mitigating warpage of circuit boards during reflow processes.

FIG. 3 is a block diagram of an additional exemplary implementation of an apparatus for mitigating warpage of circuit boards during reflow processes.

FIG. 4 is a block diagram of a further exemplary implementation of an apparatus for mitigating warpage of circuit boards during reflow processes.

FIG. 5 is a block diagram of another exemplary implementation of an apparatus for mitigating warpage of circuit boards during reflow processes.

FIG. 6 is a flow diagram of an exemplary method for mitigating warpage of circuit boards during reflow processes.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes various apparatuses, systems, and methods for mitigating warpage of circuit boards during reflow processes. As will be explained in greater detail below, embodiments of the instant disclosure may involve temporarily interfacing a removable stiffening brace with a bottom surface of a circuit board prior to a reflow process in which at least one component is soldered to the circuit board. These embodiments may also involve securing the removable stiffening brace to the bottom surface of the circuit board by way of one or more fasteners. By securing the removable stiffening brace to the circuit board in this way, these embodiments may enable the removable stiffening brace to provide structural support to the circuit board, thereby preventing the circuit board from warping during the reflow process.

Accordingly, these embodiments may effectively ensure that the components sitting on the top surface of the circuit board above the removable stiffening brace achieve full connectivity with the remaining components after completion of the reflow process. With full connectivity, the circuit board may include, create, and/or maintain one or more closed circuits that work as expected such that the computing device in which the circuit board resides is operable for its intended purpose.

In other words, none of the solder points between the connection terminals and/or leads on the components and the corresponding contact pads on the circuit board may suffer from imperfections that disturb and/or harm the circuit board's communicative integrity. Such solder point imperfections include, without limitation, non-wet open defects, head-on-pillow defects, bridged solder joints, stretched solder joints, head-on-pillow open defects, combinations and/or variations of one or more of the same, and/or any other solder point imperfections.

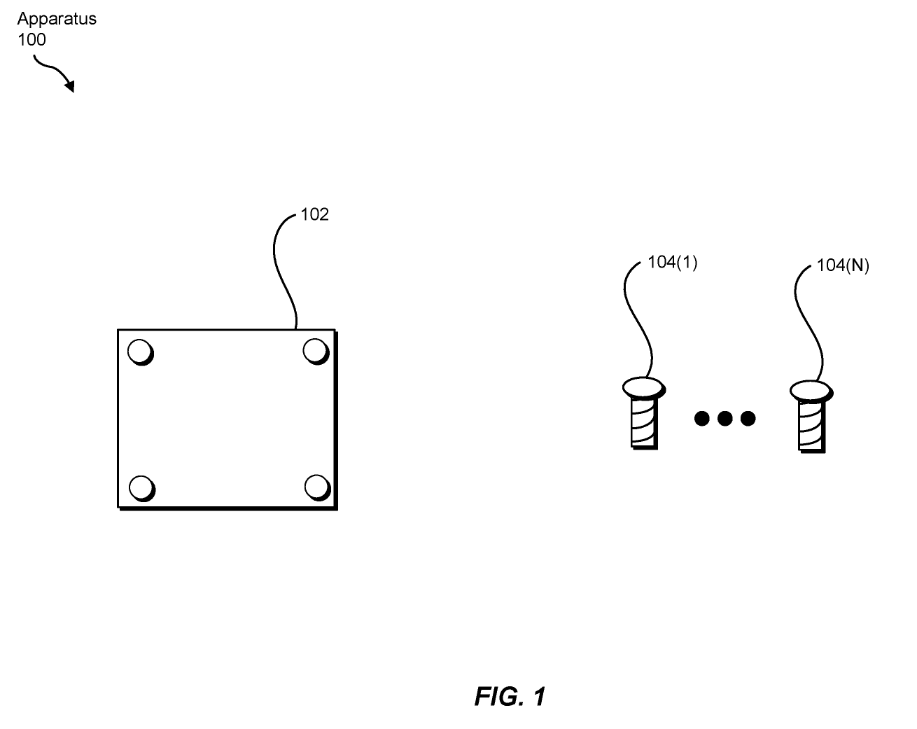

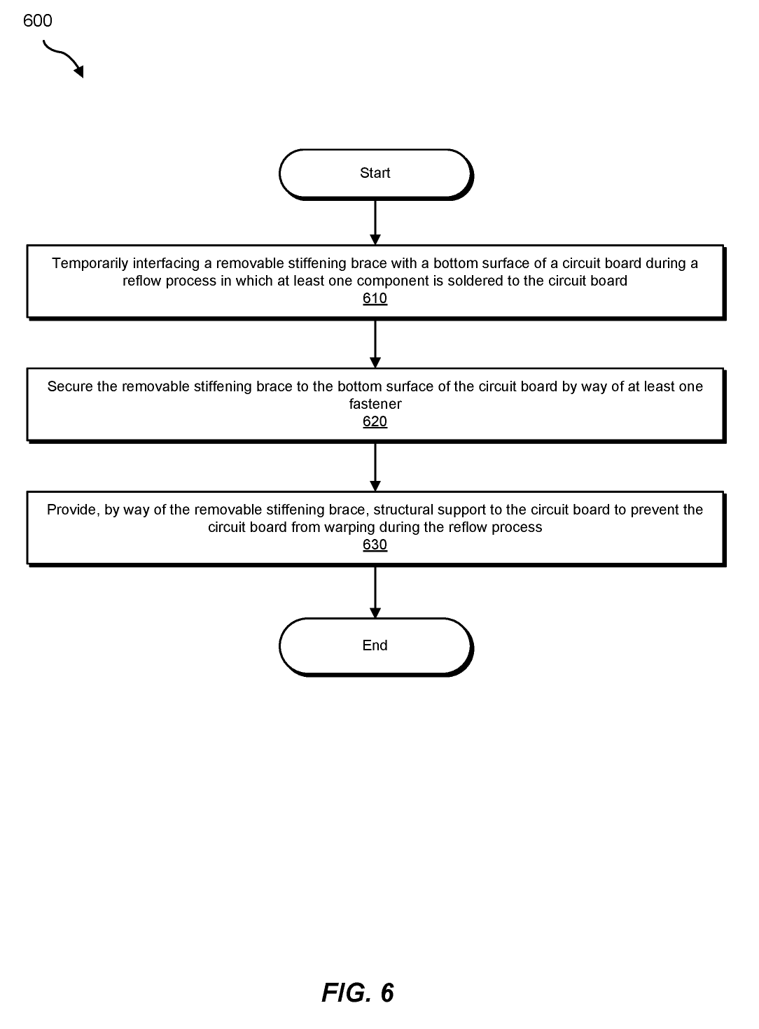

The following will provide, with reference to FIGS. 1-5, examples of apparatuses and/or corresponding components and implementations that facilitate mitigating warpage of circuit boards during reflow processes. In addition, the following will provide, with reference to FIG. 6, examples of methods for mitigating warpage of circuit boards during reflow processes.

FIG. 1 shows an exemplary apparatus 100 for mitigating warpage of circuit boards during reflow processes. As illustrated in FIG. 1, apparatus 100 may include and/or represent a removable stiffening brace 102 and fasteners 104(1)-(N). The term “stiffening brace,” as used herein, generally refers to any type or form of physical material, structure, and/or support feature that interfaces with and/or fastens to a surface of a circuit board. In one example, removable stiffening brace 102 may include and/or represent a sheet, plate, and/or frame that is fixed to the bottom surface of a circuit board prior to a reflow process. In this example, removable stiffening brace 102 may be placed and/or positioned on the bottom side of the circuit board underneath and/or opposite one or more components located on the top surface of the circuit board.

Removable stiffening brace 102 may include and/or form any suitable shape. In some examples, removable stiffening brace 102 may form a square, a circle, and/or a rectangle. Additional examples of shapes formed by removable stiffening brace 102 include, without limitation, triangles, pentagons, hexagons, octagons, ovals, diamonds, parallelograms, combinations or variations of one or more of the same, and/or any other suitable shapes.

In some examples, removable stiffening brace 102 may be formed to curve upward and/or downward relative to its edges. In other words, removable stiffening brace 102 may represent a curved base that is not uniformly parallel with circuit board 202. In one example, instead of being a solid piece of material, removable stiffening brace 102 may have a truss and/or beam structure. Additionally or alternatively, removable stiffening brace 102 may include and/or represent a multi-layer design that incorporates different metals with differing thermal expansions. Removable stiffening brace 102 may take on and/or embody any or all of these qualities and/or characteristics as needed to achieve optimal warpage control for a given circuit board and/or configuration.

In addition, removable stiffening brace 102 may be of any suitable dimensions. In one example, removable stiffening brace 102 may encompass and/or follow the perimeter of the package of a component (e.g., a lidless integrated circuit) that is sitting atop solder pads on the top surface of the circuit board prior to initiation of the reflow process. In another example, removable stiffening brace 102 may encompass and/or follow the outer perimeter of a group of components that are sitting atop solder pads on the top surface of the circuit board prior to initiation of the reflow process.

Removable stiffening brace 102 may include and/or contain any of a variety of materials. Examples of such materials include, without limitation, plastics, ceramics, polymers, metals, composites, combinations or variations of one or more of the same, and/or any other suitable materials.

In some examples, removable stiffening brace 102 may serve as a foundation and/or base that provides structural support, tension, and/or integrity to the circuit board during the reflow process. In one example, removable stiffening brace 102 may temporarily interface with the circuit board. For example, removable stiffening brace 102 may be placed and/or positioned against the bottom surface of the circuit board prior to the reflow process in which various components are soldered to the top surface of the circuit board. In this example, removable stiffening brace 102 may reside on the bottom side of the circuit board during the reflow process. While residing on the bottom side of the circuit board, removable stiffening brace 102 may provide structural support to the circuit board to mitigate warpage suffered by the circuit board during the reflow process.

The terms “bottom surface” and “top surface,” as used herein, are generally relative in nature. For example, the bottom surface may become the top surface, and vice versa, when the circuit board is flipped upside down and/or inverted. The terms “bottom surface” and “top surface” are used mainly to distinguish one side of the circuit board from another and/or describe how removable stiffening brace 102 is oriented relative to the circuit board during the reflow process.

In some examples, removable stiffening brace 102 may include and/or form one or more holes and/or receptacles designed to accept, receive, and/or mate with fasteners 104(1)-(N). In one example, these holes and/or receptacles may be threaded. By accepting, receiving, and/or mating with fasteners 104(1)-(N), these holes and/or receptacles may enable fasteners 104(1)-(N) to secure and/or hold removable stiffening brace 102 in place against the circuit board.

Additionally or alternatively, removable stiffening brace 102 may include and/or form one or more inserts or pins that fit into holes on the circuit board. In one example, these inserts or pins may include and/or form the holes and/or receptacles designed to accept, receive, and/or mate with fasteners 104(1)-(N). In this example, the inserts or pins may be formed to fit precisely and/or snuggly within the holes on the circuit board, thereby causing structural tension that effectively holds and/or secures removable stiffening brace 102 in place with respect to the circuit board.

The term “fastener,” as used herein, generally refers to any type or form of connector, mechanism, and/or hardware that mechanically secures and/or attaches a stiffening brace to a circuit board. In one example, fasteners 104(1)-(N) may each represent one side or both sides of a coupling, fitting, and/or assembly that facilitates physically mounting, attaching, connecting, and/or interfacing removable stiffening brace 102 to the circuit board. Examples of fasteners 104(1)-(N) include, without limitation, screws, pins, spring-loaded locking mechanisms, adhesives, bolts, latches, anchors, ties, straps, portions of one or more of the same, combinations and/or variations of one or more of the same, and/or any other suitable fasteners.

Fasteners 104(1)-(N) may each include and/or form any suitable shape. In some examples, fasteners 104(1)-(N) may form a circle, an oval, a square, a cube, a cylinder, portions of one or more of the same, and/or variations or combinations of one or more of the same. Additionally or alternatively, fasteners 104(1)-(N) may each include and/or form a thread that runs along the surface. This threading may facilitate securing and/or locking fasteners 104(1)-(N) to holes and/or receptacles.

Fasteners 104(1)-(N) may each include and/or contain any of a variety of materials. Examples of such materials include, without limitation, metals, plastics, ceramics, polymers, composites, combinations or variations of one or more of the same, and/or any other suitable materials. In addition, fasteners 104(1)-(N) may each be of any suitable dimensions.

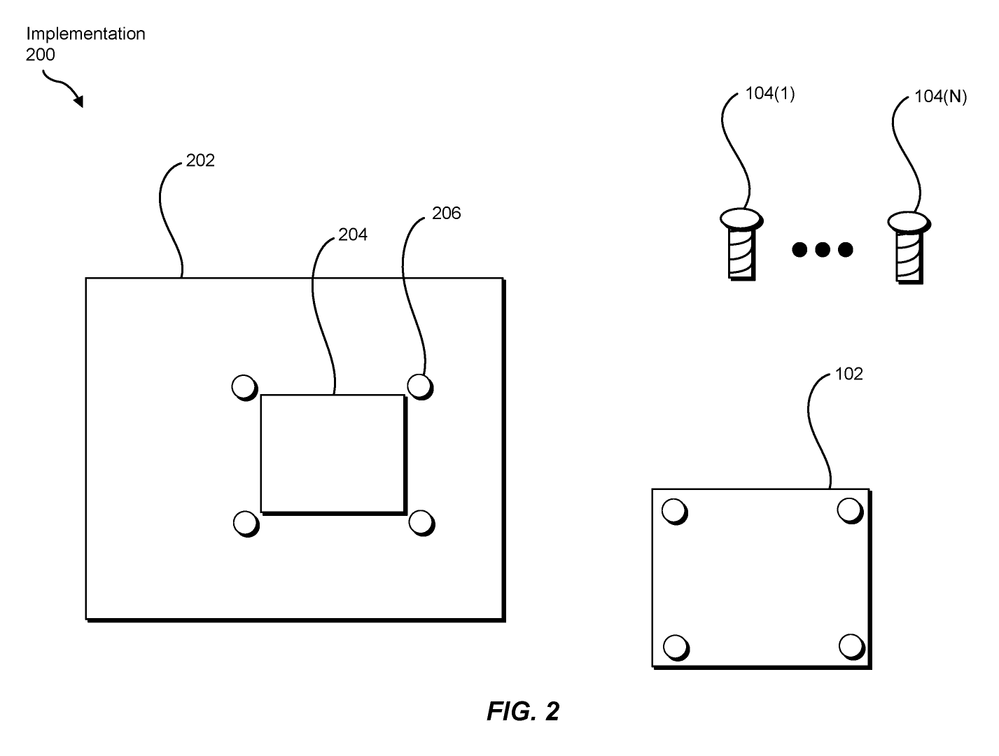

FIG. 2 shows an exemplary implementation 200 of apparatus 100 from FIG. 1. As illustrated in FIG. 2, implementation 200 may include and/or involve removable stiffening brace 102 and fasteners 104(1)-(N). In addition, implementation 200 may include and/or involve a circuit board 202 and a component 204. In this example, component 204 may be placed atop one or more corresponding solder pads on the top surface of circuit board 202 in preparation for a reflow soldering process.

Examples of component 204 include, without limitation, ASICs, integrated circuits, lidless integrated circuits, microprocessors, microcontrollers, Central Processing Units (CPUs), Field-Programmable Gate Arrays (FPGAs), memory devices, High Bandwidth Memory (HBM), Random Access Memory (RAM), Read Only Memory (ROM), flash memory, caches, portions of one or more of the same, variations or combinations of one or more of the same, and/or any other suitable component.

As illustrated in FIG. 2, circuit board 202 may include and/or form holes 206. In this example, holes 206 may enable fasteners 104(1)-(N) to pass through the circuit board. For example, holes 206 may facilitate the passage of fasteners 104(1)-(N) from the top side of circuit board 202 to the bottom side of circuit board 202. Fasteners 104(1)-(N) may enter and/or be tightened to the threaded holes and/or receptacles of removable stiffening brace 102 on the bottom side of circuit board 202. By doing so, fasteners 104(1)-(N) may effectively secure and/or fix removable stiffening brace 102 to the bottom surface of circuit board 202.

In some examples, holes 206 may also be used to attach and/or secure a heatsink atop component 204 after completion of the reflow process. For example, after completion of the reflow process and removal of stiffening brace 102, an automated system or a human technician may set a heatsink atop component 204 and then pass one or more screws through holes 206 to facilitate securing the heatsink atop component 204.

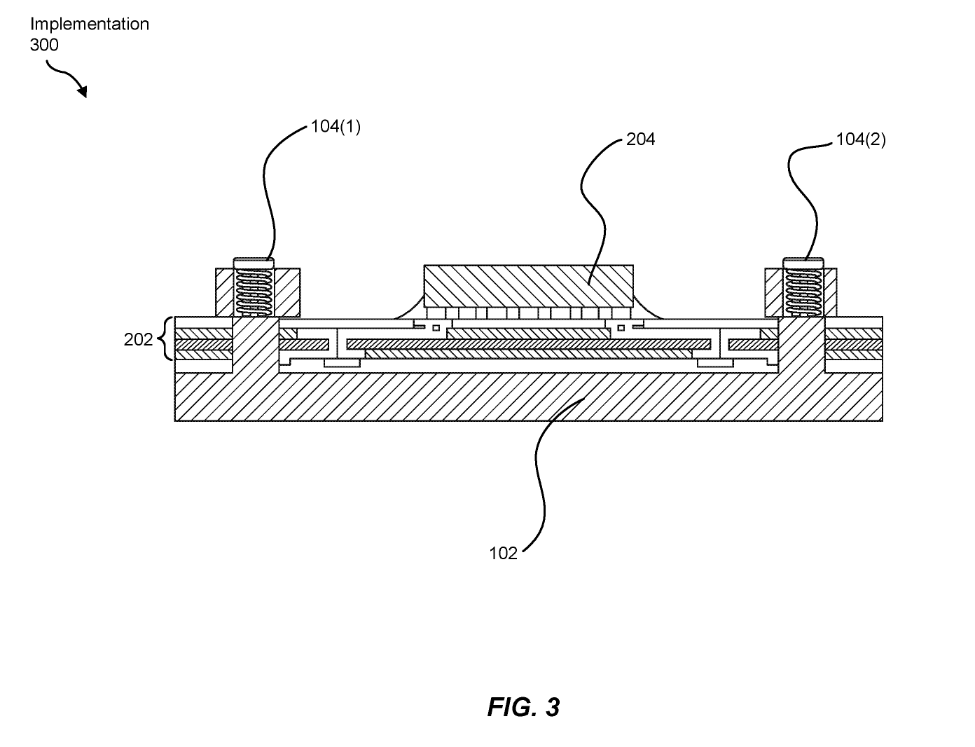

FIG. 3 shows a cross section of an exemplary implementation 300 of apparatus 100 from FIG. 1. As illustrated in FIG. 3, implementation 300 may include and/or involve removable stiffening brace 102, fasteners 104(1)-(2), circuit board 202, and/or component 204. In one example, removable stiffening brace 102 may temporarily interface with the bottom surface of circuit board 202 prior to a reflow process in which component 204 is soldered to circuit board 202. In this example, removable stiffening brace 102 may be secured and/or fixed to the bottom surface of circuit board 202 by way of at least fasteners 104(1)-(2). In this way, removable stiffening brace 102 may provide structural support to circuit board 202 during the reflow process. As a result, removable stiffening brace 102 may prevent circuit board 202 from warping during the reflow process.

As illustrated in FIG. 3, removable stiffening brace 102 may include inserts or pins that fit within the holes on circuit board 202 to provide structural tension or support and/or ensure that removable stiffening brace 102 remains snuggly fastened and/or secured to the bottom surface of circuit board 202. In one example, fasteners 104(1)-(2) may secure removable stiffening brace 102 to the bottom surface of circuit board 202 by locking the inserts or pins that fit within and/or are inserted through the holes on circuit board 202.

In one example, an automated system and/or robot may place and/or secure removable stiffening brace 102 to the bottom surface of circuit board 202 by way of fasteners 104(1)-(2). Alternatively, a human technician may place and/or secure removable stiffening brace 102 to the bottom surface of circuit board 202 by way of fasteners 104(1)-(2).

In one example, a pick-and-place machine may populate circuit board 202 with various electrical and/or electronic components, including component 204. Alternatively, a human technician may use certain tools to populate circuit board 202 with various electrical and/or electronic components, including component 204.

In some examples, removable stiffening brace 102 may remain fastened and/or secured to the bottom surface of circuit board 202 only prior to and during the reflow process. In one example, removable stiffening brace 102 may be applied to circuit board 202 by the manufacturer of circuit board 202. Alternatively, removable stiffening brace 102 may be applied to circuit board 202 by the computing equipment assembler and/or vendor responsible for assembling and/or populating circuit board 202.

After completion of the reflow process, removable stiffening brace 102 may be removed from circuit board 202. For example, an automated system and/or a robot may take off stiffening brace 102 from circuit board 202 once the reflow process has finished and/or circuit board 202 has cooled. Alternatively, a human technician may take off stiffening brace 102 from circuit board 202 once the reflow process has finished and/or circuit board 202 has cooled.

In one example, component 204 may call for and/or necessitate a heatsink that absorbs heat and/or facilitates heat transfer. For example, component 204 may include and/or represent a lidless integrated circuit. In this example, after removal of stiffening brace 102, a heatsink may be placed and/or positioned atop the lidless integrated circuit such that the heatsink makes physical and/or thermal contact with a die of the lidless integrated circuit. In addition, screws may be passed through the heatsink and/or holes 206 to facilitate securing and/or attaching the heatsink to the die of the lidless integrated circuit.

In one example, an automated system and/or a robot may place the heatsink atop the lidless integrated circuit and/or secure the heatsink to the lidless integrated circuit via the screws. Alternatively, a human technician may place the heatsink atop the lidless integrated circuit and/or secure the heatsink to the lidless integrated circuit via the screws.

In one example, fasteners 104(1)-(2) may each include and/or represent a spring-loaded locking mechanism. In this example, the spring-loaded locking mechanism may enable removable stiffening brace 102 to apply a certain amount of tension to the circuit board over a range of temperatures during the reflow process. By doing so, the spring-loaded locking mechanism may effectively mitigate warpage of circuit board 202 even as circuit board 202 undergoes a high range of temperatures during the reflow process.

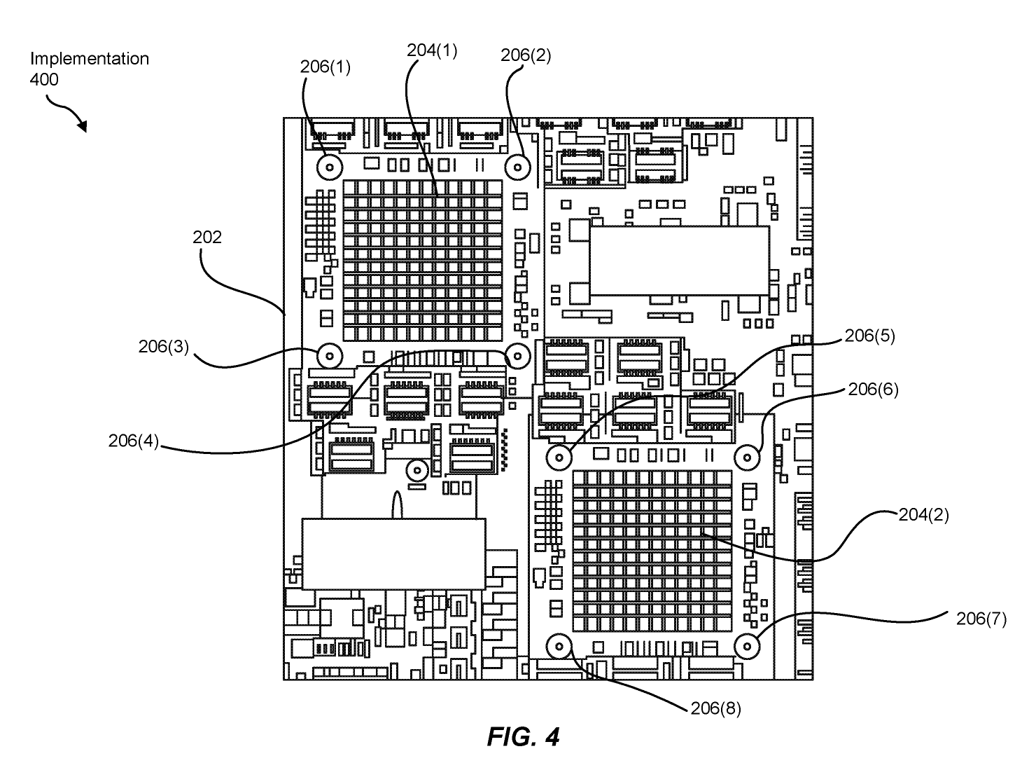

FIG. 4 shows an exemplary implementation 400 of apparatus 100 from FIG. 1. More specifically, FIG. 4 shows a top-down view of the top surface of circuit board 202, which incorporates apparatus 100 from FIG. 1. As illustrated in FIG. 4, implementation 400 may include and/or involve components 204(1) and 204(2) that are placed and/or positioned on the top surface of circuit board 202. In this example, component 204(1) may be sitting atop solder pads (not visible in FIG. 4) near holes 206(1)-(4), and component 204(2) may be sitting atop solder pads (not visible in FIG. 4) near holes 206(5)-(8).

Although not visible in FIG. 4, removable stiffening braces may be placed and/or positioned on the bottom side of circuit board 202 underneath and/or opposite components 204(1) and 204(2), respectively. In this example, fasteners may be applied to receptacles in the removable stiffening braces through holes 206(1)-(8) in circuit board 202. These fasteners may effectively secure and/or fix the removable stiffening braces in place against the bottom surface of circuit board 202. As a result, the removable stiffening braces may be able to mitigate the amount of warpage experienced by circuit board 202 during the reflow process, especially in the areas around components 204(1)-(2).

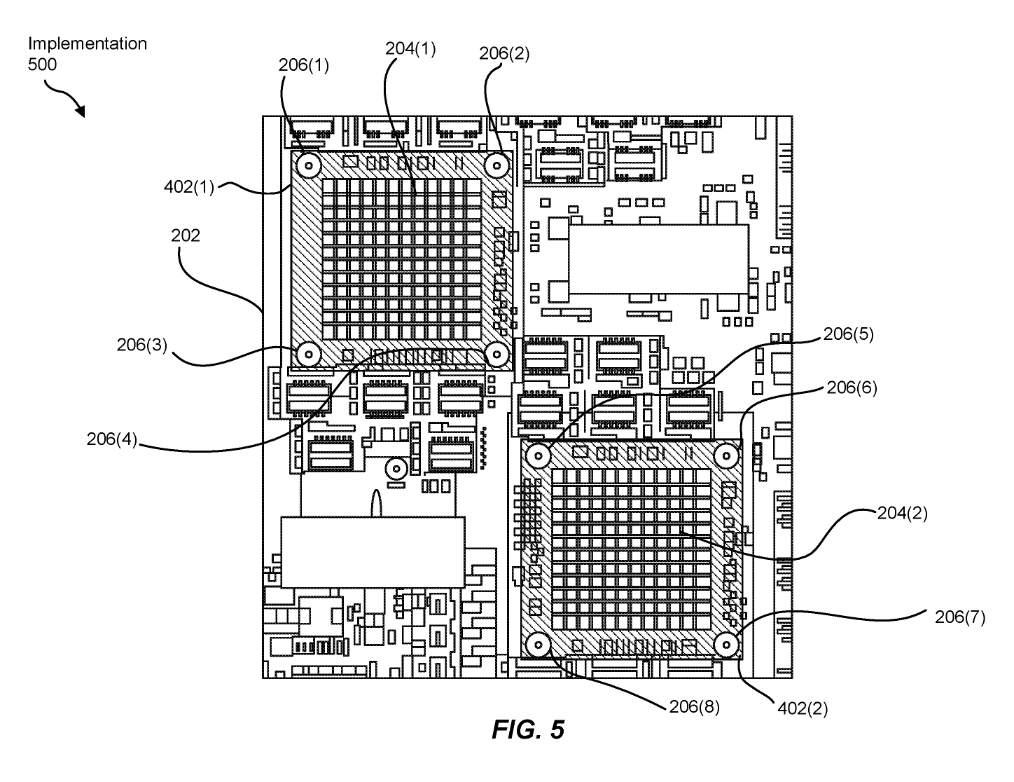

FIG. 5 shows an exemplary implementation 500 of apparatus 100 from FIG. 1. More specifically, FIG. 5 shows a top-down view of the top surface of circuit board 202, which incorporates apparatus 100 from FIG. 1. As illustrated in FIG. 5, and like implementation 400 in FIG. 4, implementation 500 may include and/or involve components 204(1) and 204(2) that are placed and/or positioned on the top surface of circuit board 202. In this example, component 204(1) may be sitting atop solder pads near holes 206(1)-(4), and component 204(2) may be sitting atop solder pads near holes 206(5)-(8).

However, unlike implementation 400 in FIG. 4, implementation 500 may include and/or involve support frames 402(1)-(2). The term “support frame,” as used herein, generally refers to any type or form of physical material, structure, and/or support feature that interfaces with and/or fastens to a surface of a circuit board. In one example, support frames 402(1)-(2) may each include and/or represent a sheet, plate, and/or border that is fixed to the top surface of a circuit board prior to a reflow process. Support frames 402(1)-(2) may be placed and/or positioned to surround and/or encompass components 204(1)-(2), respectively, on the top side of circuit board 202.

Support frames 402(1)-(2) may include and/or form any suitable shape. In some examples, support frames 402(1)-(2) may form a square, a circle, and/or a rectangle. Additional examples of shapes formed by support frames 402(1)-(2) include, without limitation, triangles, pentagons, hexagons, octagons, ovals, diamonds, parallelograms, combinations or variations of one or more of the same, and/or any other suitable shapes.

In addition, support frames 402(1)-(2) may be of any suitable dimensions. In one example, support frames 402(1)-(2) may encompass and/or follow the perimeter of the package of components 204(1)-(2), respectively.

Support frames 402(1)-(2) may include and/or contain any of a variety of materials. Examples of such materials include, without limitation, plastics, ceramics, polymers, metals, composites, combinations or variations of one or more of the same, and/or any other suitable materials.

In some examples, support frames 402(1)-(2) may reside between the top surface of circuit board 202 and the fasteners used to secure removable stiffening braces to the bottom surface of circuit board 202. For example, support frame 402(1) may be held in place surrounding component 204(1) on the top side of circuit board 202, and support frame 402(2) may be held in place surrounding component 204(2) on the top side of circuit board 202.

In one example, support frames 402(1)-(2) may provide additional structural support to circuit board 202 to prevent circuit board 202 from warping during the reflow process. As a result, support frames 402(1)-(2) may, in conjunction with the removable stiffening braces, be able to mitigate the amount of warpage experienced by circuit board 202 during the reflow process, especially in the areas around components 204(1)-(2).

In one example, an automated system and/or robot may place and/or secure support frames 402(1)-(2) to the top surface of circuit board 202 by way of fasteners 104(1)-(2). Alternatively, a human technician may place and/or secure support frames 402(1)-(2) to the top surface of circuit board 202 by way of fasteners 104(1)-(2).

In some examples, support frames 402(1)-(2) may remain fastened and/or secured to the top surface of circuit board 202 only prior to and during the reflow process. In one example, support frames 402(1)-(2) may be applied to circuit board 202 by the manufacturer of circuit board 202. Alternatively, support frames 402(1)-(2) may be applied to circuit board 202 by the computing equipment assembler and/or vendor responsible for assembling and/or populating circuit board 202.

After completion of the reflow process, support frames 402(1)-(2) may be removed from circuit board 202. For example, an automated system and/or a robot may take off support frames 402(1)-(2) from circuit board 202 once the reflow process has finished and/or circuit board 202 has cooled. Alternatively, a human technician may take off support frames 402(1)-(2) from circuit board 202 once the reflow process has finished and/or circuit board 202 has cooled.

FIG. 6 is a flow diagram of an exemplary method 600 for mitigating warpage of circuit boards during reflow processes. As illustrated in FIG. 6, method 600 may include the step of temporarily interfacing a removable stiffening brace with a bottom surface of a circuit board during a reflow process in which at least one component is soldered to the circuit board (610). This interfacing step may be performed in a variety of ways and/or contexts. For example, an automated system and/or a robot may place and/or position a removable stiffening brace against the bottom surface of a circuit board prior to initiation of a reflow process in which at least one component is soldered to the circuit board. Alternatively, a human technician may place and/or position a removable stiffening brace against the bottom surface of a circuit board prior to initiation of such a reflow process.

Returning to FIG. 6, method 600 may also include the step of securing the removable stiffening brace to the bottom surface of the circuit board by way of at least one fastener (620). This securing step may be performed in a variety of ways and/or contexts. For example, an automated system and/or a robot may secure the removable stiffening brace to the bottom surface of the circuit board by screwing and/or tightening one or more fasteners into receptacles on the removable stiffening brace. Alternatively, a human technician may secure the removable stiffening brace to the bottom surface of the circuit board by screwing and/or tightening one or more fasteners into receptacles on the removable stiffening brace.

Returning to FIG. 6, method 600 may further include the step of providing, by way of the removable stiffening brace, structural support to the circuit board to prevent the circuit board from warping during the reflow process (630). This providing step may be performed in a variety of ways and/or contexts. For example, once secured to the circuit board, the removable stiffening brace may provide structural support and/or tension to the circuit board. By doing so, the removable stiffening brace may prevent the circuit board from warping during the reflow process.

As a result, the removable stiffening brace may effectively ensure that the components sitting on the top surface of the circuit board above the removable stiffening brace achieve full connectivity with the remaining components after completion of the reflow process. With full connectivity, the circuit board may include, create, and/or maintain one or more closed circuits that work as expected such that the computing device in which the circuit board resides is operable for its intended purpose.

While the foregoing disclosure sets forth various embodiments using specific illustrations, flowcharts, and examples, each illustration component, flowchart step, operation, and/or component described and/or exemplified herein may be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a removable stiffening brace that:
temporarily interfaces with a bottom surface of a circuit board during a reflow process in which at least one component is soldered to the circuit board; and
provides structural support to the circuit board to prevent the circuit board from warping during the reflow process; and
at least one fastener that secures the removable stiffening brace to the bottom surface of the circuit board during the reflow process.

2. The apparatus of claim 1, wherein:
the removable stiffening brace comprises at least one pin that is inserted through at least one hole formed in the circuit board prior to initiation of the reflow process; and
the fastener secures the removable stiffening brace to the bottom surface of the circuit board by locking the pin inserted through the hole to a top surface of the circuit board.

3. The apparatus of claim 2, wherein the removable stiffening brace is removed from the bottom surface of the circuit board after completion of the reflow process.

4. The apparatus of claim 3, wherein the component soldered to the circuit board during the reflow process comprises a lidless integrated circuit; and
further comprising a heatsink that is attached to a die of the lidless integrated circuit after the removable stiffening brace has been removed from the stiffening brace.

5. The apparatus of claim 4, wherein the heatsink is attached to the die of the lidless integrated circuit by way of the hole formed in the circuit board.

6. The apparatus of claim 2, wherein:
the fastener comprises a screw; and
the pin comprises a threaded receptacle that receives the screw.

7. The apparatus of claim 1, wherein the fastener comprises a spring-loaded locking mechanism that enables the removable stiffening brace to apply a certain amount of tension to the circuit board over a range of temperatures during the reflow process.

8. The apparatus of claim 1, further comprising a support frame that:
resides between the fastener and a top surface of the circuit board; and
provides additional structural support to the circuit board to prevent the circuit board from warping during the reflow process.

9. The apparatus of claim 1, wherein the removable stiffening brace comprises a curved base that is not uniformly parallel with the circuit board.

10. The apparatus of claim 1, wherein the removable stiffening brace comprises at least one of:
a truss structure; and
a beam structure.

11. The apparatus of claim 1, wherein the removable stiffening brace comprises at least one metal material.

12. A warpage-mitigation system comprising:
a removable stiffening brace that:
temporarily interfaces with a bottom surface of a circuit board during a reflow process in which at least one component is soldered to the circuit board;
provides structural support to the circuit board to prevent the circuit board from warping during the reflow process; and
includes at least one pin that is inserted through a hole formed in a circuit board; and
at least one fastener that secures the removable stiffening brace to the bottom surface of the circuit board during the reflow process by locking the pin inserted through the hole to a top surface of the circuit board.

13. The warpage-mitigation system of claim 12, wherein:
the removable stiffening brace comprises at least one pin that is inserted through at least one hole formed in the circuit board prior to initiation of the reflow process; and
the fastener secures the removable stiffening brace to the bottom surface of the circuit board by locking the pin inserted through the hole to a top surface of the circuit board.

14. The warpage-mitigation system of claim 13, wherein the removable stiffening brace is removed from the bottom surface of the circuit board after completion of the reflow process.

15. The warpage-mitigation system of claim 14, wherein the component soldered to the circuit board during the reflow process comprises a lidless integrated circuit; and
further comprising a heatsink that is attached to a die of the lidless integrated circuit after the removable stiffening brace has been removed from the stiffening brace.

16. The warpage-mitigation system of claim 16, wherein the heatsink is attached to the die of the lidless integrated circuit by way of the hole formed in the circuit board.

17. The warpage-mitigation system of claim 13, wherein:
the fastener comprises a screw; and
the pin comprises a threaded receptacle that receives the screw.

18. The system of claim 12, wherein the fastener comprises a spring-loaded locking mechanism that enables the removable stiffening brace to apply a certain amount of tension to the circuit board over a range of temperatures during the reflow process.

19. The system of claim 12, further comprising a support frame that:
resides between the fastener and a top surface of the circuit board; and
provides additional structural support to the circuit board to prevent the circuit board from warping during the reflow process.

20. A method comprising:
temporarily interfacing a removable stiffening brace with a bottom surface of a circuit board prior to a reflow process in which at least one component is soldered to the circuit board;
securing the removable stiffening brace to the bottom surface of the circuit board by way of at least one fastener; and
providing, by way of the removable stiffening brace, structural support to the circuit board to prevent the circuit board from warping during the reflow process.
